(19) United States
(12) Patent Application Publication
(10) Pub. No.: US 2017/0295676 A1
(43) Pub. Date: Oct. 12, 2017

(54) IMMERSION COOLED TOP-LOADING COMPUTING CARTRIDGES

(71) Applicant: HEWLETT PACKARD ENTERPRISE DEVELOPMENT LP, Houston, TX (US)

(72) Inventors: Kevin D CONN, Montgomery, TX (US); Kelly K SMITH, Spring, TX (US); Kapil Rao Papa Rao Bala GANTA, Sr., Houston, TX (US)

(21) Appl. No.: 15/511,237

(22) PCT Filed: Sep. 29, 2014
(86) PCT No.: PCT/US2014/058140

§ 371 Date: Mar. 15, 2017

(51) Int. Cl. H05K 7/20

(52) U.S. Cl. CPC H05K 7/20781

(57) ABSTRACT

A chassis in accordance with one example includes a plurality of slots to receive a plurality of top-loading computing cartridges from a top of the chassis. The chassis also includes a supply inlet on a first side of the chassis to direct cooling fluid from the first side to a second side of the chassis, and a return outlet on the second side of the chassis to expel the cooling fluid from the chassis. The plurality of computing cartridges are immersed in the cooling fluid.

### BACKGROUND

Electronic devices have temperature requirements. Heat from the use of the electronic device is controlled using cooling systems, because devices may be damaged if they overheat. Thus, heat is typically siphoned away from electronic devices using cooling systems. Examples of cooling systems include air, liquid, and immersion cooling.

### BRIEF DESCRIPTION OF THE DRAWINGS

Some examples of the present application are described with respect to the following figures:

FIG. 1 illustrates a front perspective of a multi-tiered cooling structure including multiple tanks to receive a plurality of top-loading computing cartridges, according to one example;

FIG. 2 illustrates a chassis including a plurality immersion cooled top-loading computing cartridges, according to one example;

FIG. 3 illustrates a chassis including a plurality of immersion cooled top-loading computing cartridges where a computing cartridge is individually insertable and removable from the chassis, according to one example;

FIG. 4 is an example of a flowchart illustrating a method for cooling top-loading computing cartridges by immersion cooling; and

FIG. 5 is an example of a flowchart illustrating another method for cooling top-loading computing cartridges by immersion cooling.

### DETAILED DESCRIPTION

In immersion cooling, cooling fluid may flow through or around electronic devices to prevent overheating of the devices. The heat produced by the components may be transferred to the cooling fluid to regulate the temperature of the devices. Conventional cooling systems include standard racks that are placed on their back in a tank and completely immersed in cooling fluid (i.e., submerged as a whole unit). To service or replace parts, entire rack may need to be shut down or powered down and servers lifted out of the tank which may be several inches deep. Such cooling systems may create space limitations, difficulties in accessing and servicing the hardware components, and may also lead to inefficiencies due to increased down time (i.e., from shutting down the entire rack).

Examples disclosed herein address the above needs and challenges by providing a plurality of servers in a top-loading modular form factor (i.e., a top-loading computing cartridge) that can be installed or removed from an immersion cooled tank/chassis without disrupting the operation of other servers. For example, a particular computing cartridge can be insertable or removable from a slot in the chassis, via the top, without powering down other computing cartridges in the chassis or powering down the chassis. This allows for better serviceability and less down time.

In one example, a multi-tiered cooling structure includes multiple tanks on each tier of the cooling structure. Each tank includes a plurality of top-loading computing cartridges insertable from a top of the tank. Each tank also includes a supply inlet on a first side of the tanks to direct cooling fluid from the first side to a second side, and a return outlet on the second side of the tanks to expel the cooling fluid from the tanks. The plurality of computing cartridges are immersed in the cooling fluid.

In another example, a chassis includes a plurality of slots to receive a plurality of top-loading computing cat fridges from a top of the chassis. The chassis also includes a supply inlet on a first side of the chassis to direct cooling fluid from the first side to a second side of the chassis, and a return outlet on the second side of the chassis to expel the cooling fluid from the chassis. The plurality of computing cartridges are immersed in the cooling fluid.

In another example, a method includes pumping a cooling fluid into a chassis, where the chassis includes a plurality of slots to receive a plurality of top-loading computing cartridges insertable from a top of the chassis. The method includes directing the cooling fluid through a supply inlet on a first side of the chassis, and expelling the cooling fluid through a return outlet on a second side of the chassis. The plurality of computing cartridges are immersed in the cooling fluid.

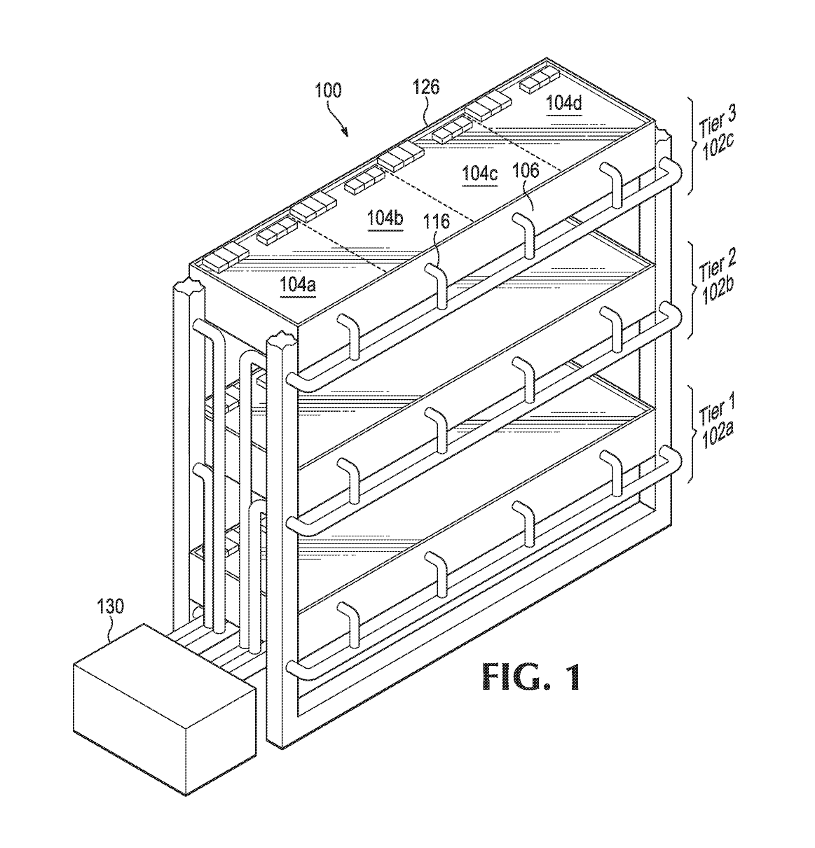

Referring now to the figures, FIG. 1 illustrates a front perspective of a multi-tiered cooling structure including multiple tanks to receive a plurality of top-loading computing cartridges, according to one example. Multi-tiered cooling structure 100 includes multiple tiers 102a-102c (Tier 1, Tier 2, and Tier 3). Each tier 102a-102c includes multiple tanks 104a-104d. Each tank 104a-104d (collectively referred to as “tank 104”) on each tier 102a-102c can accommodate a plurality of top-loading computing cartridges (not shown) that fit into slots configured to receive the computing cartridges from above (i.e., the top of the tanks 104). Thus, each computing cartridge can be independently inserted into a tank 104.

Tank 104 includes a supply inlet 116 on a first side 106 (e.g., the front side) to receive the cooling fluid and direct the cooling fluid to a second side 126 (e.g., the backside/opposite side) of the tank 104. Tank 104 also includes a return outlet (not shown) on the second side 126 to direct an outflow of the cooling liquid and expel the cooling liquid from the tank 104. In one example, the expelled cooling fluid enters a heat exchanger 130 to transfer the heat from the cooling fluid so that the cooling fluid may be pumped back into the tanks 104a-104d. In some examples, the cooling fluid can be a dielectric fluid or mineral oil that is not electrically conductive and has better heat properties than water, for example.

The plurality of computing cartridges are immersed in the cooling fluid as the cooling fluid is directed into and expelled from the tank 104. The heat generated by the computing cartridges are removed by the cooling fluid. Although FIG. 1 illustrates the multi-tiered cooling structure 100 as including three tiers, implementations should not be limited as this was done for illustration purposes. For example, the multi-tiered cooling structure 100 may include less than three tiers (e.g., two tiers) or greater than three tiers (e.g., four tiers). Further, although FIG. 1 illustrates four tanks 104a-104d on each of the multiple tiers 102a-102c, this was done for illustration purposes and not for limiting implementations. For example, each tier 102 may include less than four tanks or greater than four tanks.

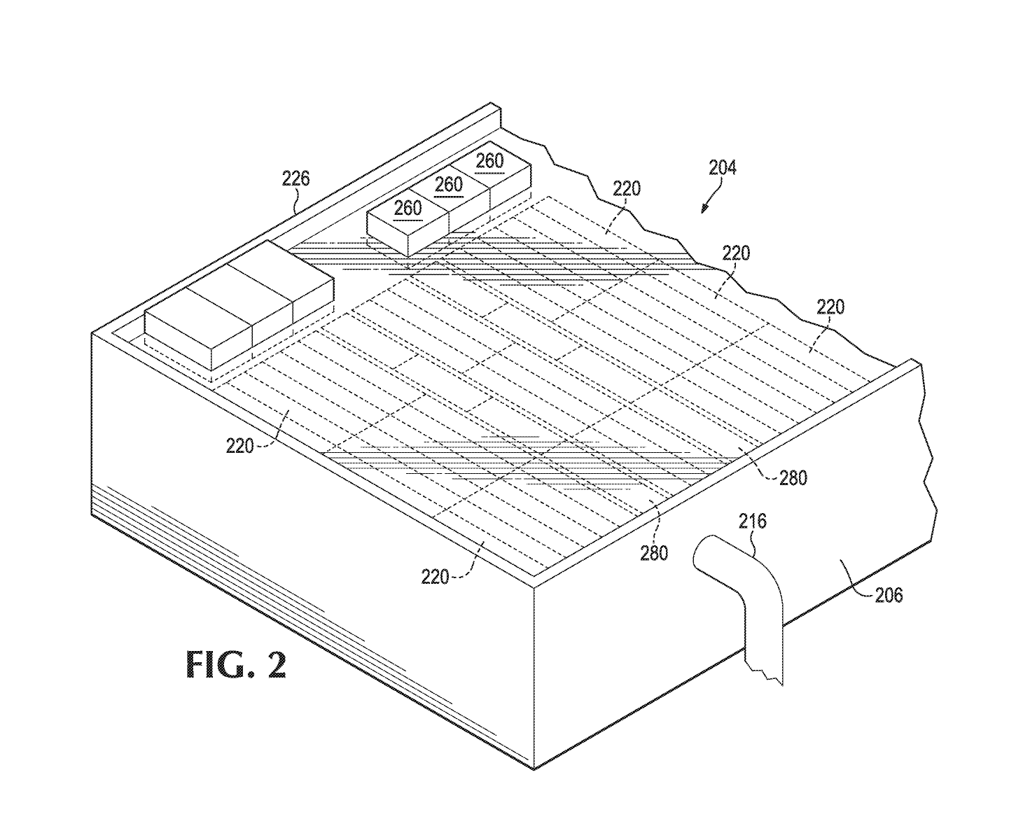

FIG. 2 illustrates a chassis including a plurality immersion cooled top-loading computing cartridges, according to one example. In the example of FIG. 2, chassis 204 includes a plurality of top-loading computing cartridges 220 inserted into the chassis 204. Chassis 204 includes a supply inlet 216 on a front side 206 to direct cooling liquid from the front side 216 to a backside 226, and a return outlet (not shown) on the backside 226 to expel the cooling liquid from the chassis 204. As the cooling fluid is directed from the front side 206 to the back side 226 of the chassis 204, the computing cartridges 220 are immersed in the cooling fluid to remove heat generated by the computing cartridges 220.

In some examples, chassis 204 also includes other devices 260 such as power components that may not be immersed in the cooling fluid. In other examples, chassis 204 can include switches 280 (or similar devices) that may be immersed in the cooling fluid and collocated with the computing cartridges 220.

Computing cartridges 220 can be server cartridges, microservers, servers and/or other type of electrical component in which the temperature may be regulated by immersion cooling, for example. As described above, computing cartridges 220 are top-loading computing cartridges. Further computing cartridges 220 are hot pluggable into the chassis 204. As used herein, “hot-pluggable” or “hot-plug” means a computing cartridge 220 can be inserted or removed from the chassis 204 without disrupting the operation of another cartridge.

Accordingly, in some examples, a computing cartridge 220 is insertable/removable from the chassis (via the top) without powering down or shutting down any other computing cartridge 220 or the chassis 204, thereby improving serviceability and reducing downtime.

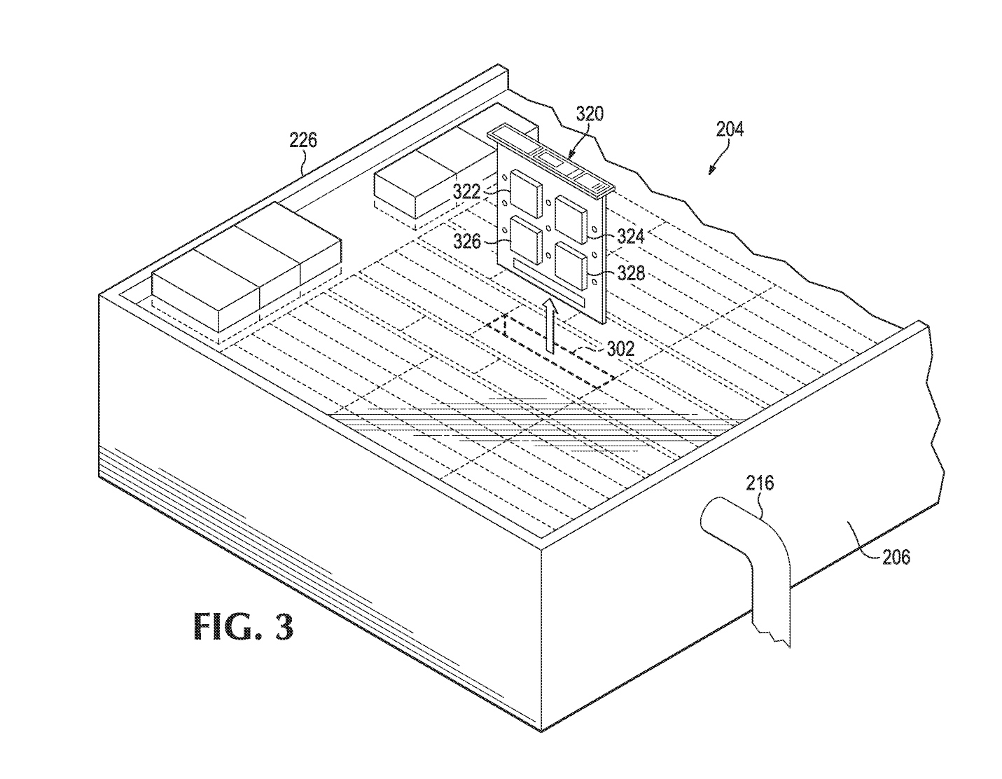

FIG. 3 illustrates a chassis including a plurality of immersion cooled top-loading computing cartridges where a computing cartridge is individually insertable and removable from the chassis, according to one example. In the example of FIG. 3, computing cartridge 320 is insertable/removable from a slot 302 of the chassis 204 without disrupting the operation of the chassis 204 and other computing cartridges.

Computing cartridge 320 can be a server cartridge, a microserver, a server and/or other type of electrical component in which the temperature may be regulated by immersion cooling, for example. Computing cartridge 320 can include additional elements thereon. For example, computing cartridge 320 can include a first electronic device 322, second electronic device 324, third electronic device 326, and fourth electronic device 328 to perform the functionalities of computing cartridge 320.

In one example, electronic devices 322, 324, 326, 328 may be a set of electronic devices configured to optimize performance of a specific application. By way of illustration, if computing cartridge 320 is designed to serve as a web server, first electronic device 322 may serve as a data store (e.g., hard disk, solid state drive, etc.) on which web content is stored, and electronic devices 322, 324, and 326 may be processors that receive and/or respond to incoming requests for system resources.

The electronic devices 322, 324, 326, 328 of computing cartridge 320 are immersed into the cooling fluid and cooled as the cooling fluid flows from the front side 206 (via inlet 216) to the backside 226 (via an outlet) of the chassis 204. Computing cartridge 320 is removable from the chassis 204 without disrupting the operation of other computing cartridges within the chassis 204. For example, computing cartridge 320 can be powered down and removed from the slot 302 (via the top of the chassis) while maintaining power to the other computing cartridges of the chassis 204.

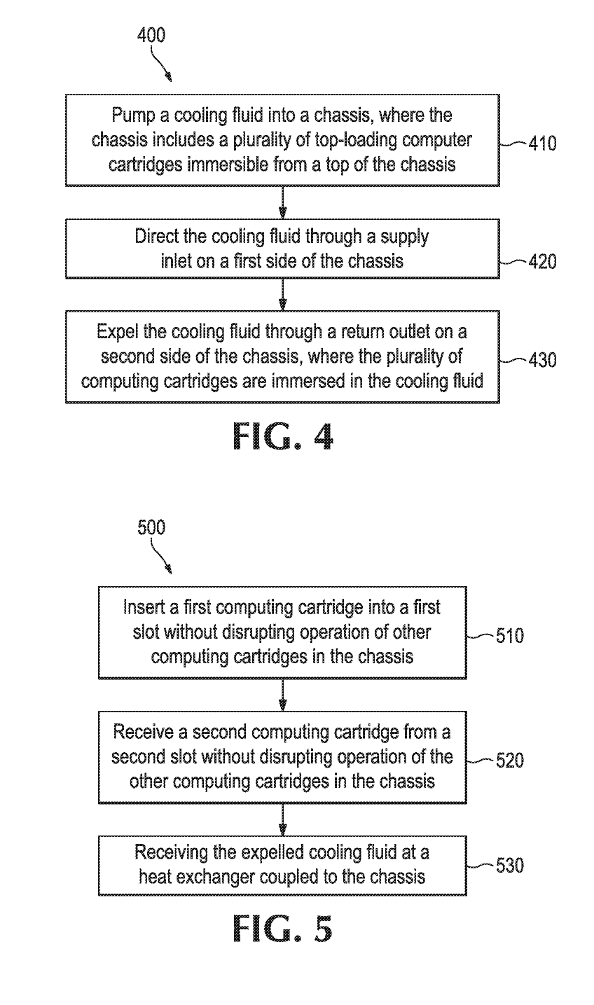

FIG. 4 is an example of a flowchart illustrating a method for cooling top-loading computing cartridges by immersion cooling, according to one example. Method 400 may be implemented, for example, in the form of executable instructions stored on a non-transitory computer-readable storage medium and/or in the form of electronic circuitry.

Method 400 includes pumping a cooling fluid into a chassis, where the chassis includes a plurality of top-loading computing cartridges insertable from a top of the chassis, at 410. For example, cooling fluid is pumped into chassis 204. A pump may be included as part of the cooling structure 100 of FIG. 1 or coupled to the chassis 204. In one example, the cooling fluid may be stagnant until the pump operates to pump the cooling fluid into the chassis. In this example, the cooling fluid may remain within the pump or may be located within the chassis. The pump may enable the flow of the cooling fluid. In another example, pumping the cooling fluid into the chassis includes immersing the computing cartridges within the chassis with cooling fluid.

Method 400 includes directing the cooling fluid through a supply inlet on a first side of the chassis, at 420. For example, by directing the cooling fluid through the supply inlet, the cooling fluid may flow from the front side to the backside (i.e., the opposite side) of the chassis. In this example, the cooling fluid may be directed across the plurality of computing cartridges in a horizontal manner.

Method 400 includes expelling the cooling fluid through a return outlet on a second side of the chassis, where the plurality of computing cartridges are immersed in the cooling fluid, at 430. The second side of the chassis is located opposite from the first side of the chassis. In this example, the cooling fluid may flow through the inlet on the first side to the outlet on the opposite side of the chassis. In some examples, method 400 of FIG. 4 includes additional steps in addition to and/or in lieu of those depicted in FIG. 4.

FIG. 5 is an example of a flowchart illustrating another method for cooling top-loading computing cartridges by immersion cooling. Method 500 may be implemented, for example, in the form of executable instructions stored on a non-transitory computer-readable storage medium and/or in the form of electronic circuitry.

Method 500 includes inserting a first computing cartridge into a first slot without disrupting operation of other computing cartridges in the chassis, at 510. For example, a computing cartridge may be inserted into a slot within the chassis without removing power from the other computing cartridges within the chassis.

Method 500 includes receiving a second computing cartridge from a second slot without disrupting operation of the other computing cartridges in the chassis, at 520. For example, a computing cartridge may be powered down and removed from a slot within the chassis without removing power from the other computing cartridges within the chassis.

Method 500 also includes receiving the expelled cooling fluid at a heat exchanger coupled to the chassis, at 530. For example, upon expelling the cooling fluid from the chassis, a heat exchanger may accept the expelled cooling fluid. The heat exchanger may transfer heat from the cooling fluid to another medium within the heat exchanger. In this example, the cooling fluid may be pumped back into the chassis. In this manner, the cooling fluid remains in a continuous loop from the chassis into the heat exchanger and back to the chassis. Looping the cooling fluid through the chassis and the heat exchanger, the chassis includes a continuous flow of the cooling fluid to regulate the temperature of the plurality of computing cartridges within the chassis. In some examples, method 500 of FIG. 5 includes additional steps in addition to and/or in lieu of those depicted in FIG. 5.

The techniques described above may be embodied in a computer-readable medium for configuring a computing system to execute the method. The computer-readable media may include, for example and without limitation, any number of the following non-transitive mediums: magnetic storage media including disk and tape storage media; optical storage media such as compact disk media (e.g., CD-ROM, CD-R, etc.) and digital video disk storage media; holographic memory; nonvolatile memory storage media including semiconductor-based memory units such as FLASH memory, EEPROM, EPROM, ROM; ferromagnetic digital memories; volatile storage media including registers, buffers or caches, main memory, RAM, etc.; and the Internet, just to name a few. Other new and obvious types of computer-readable media may be used to store the software modules discussed herein. Computing systems may be found in many forms including but not limited to mainframes, minicomputers, servers, workstations, personal computers, notepads, personal digital assistants, tablets, smartphones, various wireless devices and embedded systems, just to name a few.

In the foregoing description, numerous details are set forth to provide art understanding of the present disclosure. However, it will be understood by those skilled in the art that the present disclosure may be practiced without these details. While the present disclosure has been disclosed with respect to a limited number of examples, those skilled in the art will appreciate numerous modifications and variations therefrom. It is intended that the appended claims cover such modifications and variations as fall within the true spirit and scope of the present disclosure.

What is claimed is:

1. A multi-tiered cooling structure, comprising:
multiple tanks on each tier of the cooling structure, wherein each tank includes:
a plurality of top-loading computing cartridges insertable from a top of the tanks;
a supply inlet on a first side of the tanks to direct cooling fluid from the first side to a second side; and
a return outlet on the second side of the tanks to expel the cooling fluid from the tanks,
wherein the plurality of computing cartridges are immersed in the cooling fluid.

2. The multi-tiered cooling structure of claim 1, wherein each tank includes a plurality of slots to receive the plurality of computing cartridges from the top of the tanks.

3. The multi-tiered cooling structure of claim 1, wherein a computing cartridge of the plurality of computing cartridges is insertable and removable from a tank without a disruption to other computing cartridges.

4. The multi-tiered cooling structure of claim 1, wherein a computing cartridge of the plurality of computing cartridges is insertable and removable from a tank without powering down the tank.

5. The multi-tiered cooling structure of claim 4, wherein the computing cartridge is insertable and removable from the tank without powering down any of the multiple tanks.

6. The multi-tiered cooling structure of claim 4, wherein the computing cartridge is insertable and removable from the tank without powering down other computing cartridges of the plurality of computing cartridges.

7. The multi-tiered cooling structure of claim 1, further comprising a heat exchanger to receive the expelled cooling fluid from the return outlet of the tanks.

8. A chassis, comprising:
a plurality of slots to receive a plurality of top-loading computing cartridges from a top of the chassis;
a supply inlet on a first side of the chassis to direct cooling fluid from the first side to a second side of the chassis; and
a return outlet on the second side of the chassis to expel the cooling fluid from the chassis,
wherein the plurality of computing cartridges are immersed in the cooling fluid.

9. The chassis of claim 8, wherein a computing cartridge of the plurality of computing cartridges is insertable and removable from the top of the chassis without a disruption to the other computing cartridges of the plurality of computing cartridges.

10. The chassis of claim 9, wherein the computing cartridge is powered down when the computing cartridge is to be removed from the chassis, while power is maintained to the chassis and to the other computing cartridges.

11. The chassis of claim 8, wherein the cooling fluid is directed in a horizontal manner across the plurality of computing cartridges from the first side of the chassis to the second side of the chassis.

12. A method, comprising:
pumping a cooling fluid into a chassis, wherein the chassis includes a plurality of slots to receive a plurality of top-loading computing cartridges insertable from a top of the chassis;
directing the cooling fluid through a supply inlet on a first side of the chassis; and
expelling the cooling fluid through a return outlet on a second side of the chassis,
wherein the plurality of computing cartridges are immersed in the cooling fluid.

13. The method of claim 12, further comprising:
inserting a first computing cartridge into a first slot without disrupting operation of other computing cartridges in the chassis; and
removing a second computing cartridge from a second slot without disrupting operation of the other computing cartridges in the chassis.

14. The method of claim 12, wherein directing the cooling fluid through the supply inlet comprises directing the cooling fluid in a horizontal manner across the plurality of computing cartridges.

15. The method of claim 12, further comprising receiving the expelled cooling fluid at a heat exchanger coupled to the chassis.
